(19) United States
(12) Patent Application Publication
(10) Pub. No.: US 2025/0067817 A1
(43) Pub. Date: Feb. 27, 2025

(54) CURRENT LEAKAGE DETECTION DEVICE

(71) Applicant: DENSO CORPORATION, Kariya-city (JP)

(72) Inventor: Tomomichi MIZOGUCHI, Kariya-city (JP)

(73) Assignee: DENSO CORPORATION, Kariya-city (JP)

(21) Appl. No.: 18/945,827

(22) Filed: Nov. 13, 2024

Related U.S. Application Data
(63) Continuation of application No. PCT/JP2023/015508, filed on Apr. 18, 2023.

(30) Foreign Application Priority Data
May 13, 2022 (JP) 2022-079779

(51) Int. Cl. G01R 31/52; B60L 3/00; G01R 31/00

(52) U.S. Cl. CPC G01R 31/52; B60L 3/0069; G01R 31/006

(57) ABSTRACT

A current leakage detection device includes a first voltage-dividing circuit, a second voltage-dividing circuit, a switching unit, and a controller configured to detect current leakage. The controller performs: a first input step of switching the second voltage-dividing circuit to the current-carrying state and inputting a first divided voltage value from the first voltage-dividing circuit and a second divided voltage value from the second voltage-dividing circuit; a second input step of switching the second voltage-dividing circuit to the current-blocked state and inputting a third divided voltage value from the first voltage-dividing circuit; a characteristic determination step of determining whether there is an abnormality in the first voltage-dividing circuit and the second voltage-dividing circuit based on the first divided voltage value and the second divided voltage value; and a current leakage detection step of detecting the current leakage based on the first divided voltage value and the third divided voltage value.

### CROSS-REFERENCE TO RELATED APPLICATION

The present application is a continuation application of International Application No. PCT/JP2023/015508, filed on Apr. 18, 2023, which claims priority to Japanese Patent Application No. 2022-079779, filed on May 13, 2022. The contents of these applications are incorporated herein by reference in their entirety.

### BACKGROUND

### Technical Field

The disclosure of the present application relates to a current leakage detection device.

### Background Art

A conventional vehicle such as a hybrid vehicle or an electric vehicle is equipped with a high-voltage battery and includes a high-voltage circuit. In such a vehicle, the high-voltage circuit is usually electrically insulated from a vehicle body (a body ground, a frame ground) for the purpose of security. Moreover, in this case, there is provided a current leakage detection device (an insulation resistance detection circuit) for detecting an insulation state (ground fault) between the high-voltage circuit and the vehicle body.

### SUMMARY

In the present disclosure, provided is a current leakage detection device as the following.

The current leakage detection device includes a first voltage-dividing circuit, a second voltage-dividing circuit, a switching unit configured to be able to switch between a current-carrying state and a current-blocked state of the second voltage-dividing circuit, and a controller configured to detect current leakage. The controller performs: a first input step of switching the second voltage-dividing circuit to the current-carrying state and inputting a first divided voltage value from the first voltage-dividing circuit and a second divided voltage value from the second voltage-dividing circuit; a second input step of switching the second voltage-dividing circuit to the current-blocked state and inputting a third divided voltage value from the first voltage-dividing circuit; a characteristic determination step of determining whether there is an abnormality in the first voltage-dividing circuit and the second voltage-dividing circuit based on the first divided voltage value and the second divided voltage value; and a current leakage detection step of detecting the current leakage based on the first divided voltage value and the third divided voltage value.

### BRIEF DESCRIPTION OF THE DRAWINGS

The above and other objects, features, and advantages of the present disclosure will become more apparent from the following detailed description made with reference to the accompanying drawings. The drawings are as follows.

FIG. 1 is a configuration diagram of a vehicle-mounted power supply system.

FIG. 2 is a flowchart of a current leakage detection process.

FIGS. 3A to 3B are a joint schematic diagram illustrating a connection state of a voltage-dividing circuit.

FIG. 4 is a timing chart illustrating an input timing of a divided voltage value.

FIGS. 5A to 5B are a joint diagram to assist in explaining a detection error of the voltage-dividing circuit.

FIG. 6 is a flowchart of a current leakage detection process of a second embodiment.

FIG. 7 is a timing chart showing an input timing of an initial value.

FIG. 8 is a configuration diagram of a current leakage detection device of a third embodiment.

FIG. 9 is a timing chart showing an input timing of an initial value according to a comparative example.

FIG. 10 is a timing chart showing an input timing of an initial value of a third embodiment.

FIG. 11 is a diagram illustrating an end-to-end voltage when an insulation resistance is lowered.

FIGS. 12A to 12B are a joint diagram to assist in explaining an error of a computed value.

FIG. 13 is a flowchart of a current leakage detection process of a fourth embodiment.

FIG. 14 is a configuration diagram of a current leakage detection device of a modification example.

FIG. 15 is a configuration diagram of a current leakage detection device of a modification example.

FIG. 16 is a configuration diagram of a current leakage detection device of a modification example.

### DETAILED DESCRIPTION OF THE PREFERRED EMBODIMENTS

The current leakage detection circuit according to PTL 1 is configured to detect an insulation resistance and detect lowering of detection accuracy attributed to aging, contact failure, or the like of a detection resistance of a voltage-dividing circuit.
[PTL 1] JP 2021-50964 A

In the meanwhile, the current leakage detection circuit of PTL 1 is configured to detect an insulation resistance after determining whether a value of the detection resistance is normal. In this regard, since the determination of whether the value of the detection resistance is normal requires a dedicated switch pattern separate from a switch pattern for detecting the insulation resistance, time is spent for switching the switch and measuring a signal. Thus, it is to be determined whether the value of the detection resistance is normal during a limited period of time, for example, when the vehicle starts to be powered, and it is difficult to monitor an abnormality of the detection resistance at any time, for example, while the vehicle is moving. Therefore, in a case where an abnormality of the voltage-dividing circuit occurs due to foreign matter involvement or the like while the vehicle is moving, it is difficult to deal with the abnormality.

The present disclosure is made in order to solve the above-described problem and an object of the present disclosure is to provide a current leakage detection device that is able to effectively perform characteristic determination of a voltage-dividing circuit and current leakage detection.

A current leakage detection device that solves the above-described problem is a current leakage detection device that detects current leakage between a power supply path connected to a terminal of a battery and a ground, the current leakage detection device including:
a first voltage-dividing circuit connected to the power supply path at one end and connected to the ground at another end, thus being put in a current-carrying state;
a second voltage-dividing circuit connected in parallel with respect to the first voltage-dividing circuit with one end connected to the power supply path and another end connected to the ground, thus being put in the current-carrying state;
a switching unit configured to be able to switch between the current-carrying state and a current-blocked state of the second voltage-dividing circuit; and
a controller configured to control the switching unit and input a divided voltage value of the first voltage-dividing circuit to detect the current leakage, wherein
the controller is configured to be able to input the divided voltage value from the first voltage-dividing circuit and a divided voltage value from the second voltage-dividing circuit, the controller being configured to perform:
   a first input step of controlling the switching unit to switch the second voltage-dividing circuit to the current-carrying state, inputting the first divided voltage value from the first voltage-dividing circuit, and inputting the second divided voltage value from the second voltage-dividing circuit;
   a second input step of controlling, after the first input step, the switching unit to switch the second voltage-dividing circuit to the current-blocked state and inputting a third divided voltage value from the first voltage-dividing circuit;
   a characteristic determination step of determining whether there is an abnormality in the first voltage-dividing circuit and the second voltage-dividing circuit based on the first divided voltage value and the second divided voltage value; and
   a current leakage detection step of detecting the current leakage based on the first divided voltage value and the third divided voltage value.

According to the above-described configuration, the second divided voltage value, which is to be used for the characteristic determination, is inputted at the same time as the first divided voltage value, which is to be used for the current leakage detection and the characteristic determination, is inputted in the first input step. Then, the third divided voltage value, which is to be used for the current leakage detection, is inputted in the second input step performed after the first input step. It is thus possible to input the first divided voltage value and the second divided voltage value necessary for performing the characteristic determination while the first input step and the second input step necessary for the current leakage detection are performed, more specifically, while the first input step is performed. This eliminates the necessity of switching the switching unit to make time for measuring a divided voltage value solely in order to acquire the first divided voltage value and the second divided voltage value necessary for the characteristic determination, enabling the current leakage detection and the characteristic determination to be efficiently performed. The characteristic determination can thus be performed at the same time as the current leakage detection, which makes it possible to determine an abnormality of the voltage-dividing circuits at any time, for example, while the vehicle is moving.

With reference to the drawings, description will be made below on a first embodiment where a “current leakage detection device” is applied to a vehicle-mounted power supply system of a vehicle (for example, a hybrid vehicle or an electric vehicle) equipped with, as a vehicle-mounted main machine, a rotating electrical machine. It should be noted that parts that are the same or equivalent among the embodiments hereinbelow are labeled with the same reference sign in the drawings and an explanation of the parts labeled with the same reference sign is incorporated by reference.

### First Embodiment

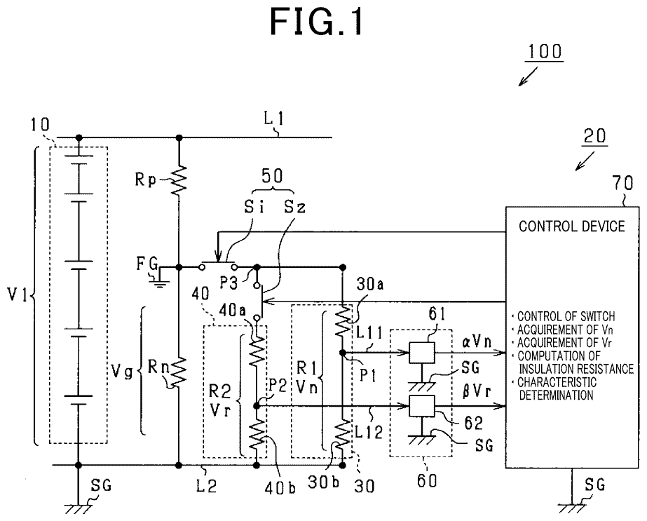

A vehicle-mounted power supply system 100 illustrated in FIG. 1 includes an assembled battery 10, which is a battery, a current leakage detection device 20, and the like. It should be noted that an electric load such as a rotating electrical machine, which is not illustrated or explained, is connected to a positive-side power supply path L1 and a negative-side power supply path L2 connected to the assembled battery 10.

The assembled battery 10 is, for example, a storage battery with an inter-terminal voltage V1 of 800 V. The assembled battery 10 includes a plurality of battery cells connected together. For example, lithium-ion storage batteries or nickel-metal hydride storage batteries are usable as the battery cells.

The positive-side power supply path L1 (corresponding to a power supply line) connected to a positive-side power supply terminal of the assembled battery 10 is electrically insulated with respect to a vehicle-side ground FG such as a vehicle body. The vehicle-side ground FG is a vehicle body or the like and corresponds to a frame ground. An insulation state (a resistance of insulation to the ground) between the positive-side power supply path L1 and the vehicle-side ground FG may be represented as an insulation resistance Rp.

Likewise, the negative-side power supply path L2 connected to a negative-side power supply terminal of the assembled battery 10 is electrically insulated with respect to the vehicle-side ground FG. An insulation state (a resistance of insulation to the ground) between the negative-side power supply path L2 and the vehicle-side ground FG may be represented as an insulation resistance Rn. It should be noted that the negative-side power supply path L2 corresponds to a ground (a signal ground SG) that determines a reference potential of a high-voltage electric circuit.

The current leakage detection device 20, which is connected to the vehicle-side ground FG and the negative-side power supply path L2, detects whether the positive-side power supply path L1 and the negative-side power supply path L2 are normally insulated with respect to the vehicle-side ground FG, that is, detects current leakage (ground fault).

The current leakage detection device 20 will be described in detail. The current leakage detection device 20 includes a first voltage-dividing circuit 30, a second voltage-dividing circuit 40 connected in parallel with respect to the first voltage-dividing circuit 30, a switching unit 50 configured to be able to switch a current-carrying state and a current-blocked state of each of the first voltage-dividing circuit 30 and the second voltage-dividing circuit 40, a detection circuit 60, and a control device 70, which is a controller that detects current leakage.

The first voltage-dividing circuit 30 is, at one end, connected to a side of the negative-side power supply path L2 and, at the other end, connected to a side of the vehicle-side ground FG and divides a voltage between the negative-side power supply path L2 and the vehicle-side ground FG (an end-to-end voltage of the first voltage-dividing circuit 30) at a voltage-dividing ratio α. The above configuration will be described in detail. The first voltage-dividing circuit 30 includes a first A detection resistance 30a and a first B detection resistance 30b, which are connected in series to form a series circuit. The first A detection resistance 30a is connected to the side of the vehicle-side ground FG and the first B detection resistance 30b is connected to the side of the negative-side power supply path L2. An end of a first output line L11 is connected to a first connection point P1 between the first A detection resistance 30a and the first B detection resistance 30b and a voltage signal (a divided voltage value) from the first voltage-dividing circuit 30 is outputted through the first output line L11.

The second voltage-dividing circuit 40 is, at one end, connected to the side of the negative-side power supply path L2 and, at the other end, connected to the side of the vehicle-side ground FG and divides a voltage between the negative-side power supply path L2 and the vehicle-side ground FG (an end-to-end voltage of the second voltage-dividing circuit 40) at a voltage-dividing ratio β. The above configuration will be described in detail. The second voltage-dividing circuit 40 includes a second A detection resistance 40a and a second B detection resistance 40b, which are connected in series to form a series circuit. The second A detection resistance 40a is connected to the side of the vehicle-side ground FG and the second B detection resistance 40b is connected to the side of the negative-side power supply path L2. An end of a second output line L12 is connected to a second connection point P2 between the second A detection resistance 40a and the second B detection resistance 40b and a voltage signal (a divided voltage value) from the second voltage-dividing circuit 40 is outputted through the second output line L12.

Next, Description will be given of the switching unit 50. The switching unit 50 includes a first switch Si and a second switch Sz, which are configured to be on-off controlled by the control device 70.

The first switch Si is, at one end, connected to the vehicle-side ground FG and, at the other end, connected in series to one end of the second switch Sz. Moreover, the first voltage-dividing circuit 30 is connected to a connection point P3 between the first switch Si and the second switch Sz. In more detail, an end of the first A detection resistance 30a (an end opposite the first connection point P1) is connected to the connection point P3 between the first switch Si and the second switch Sz. The second switch Sz is, at one end, connected in series to the first switch Si and, at the other end, connected to the second voltage-dividing circuit 40. In more detail, an end of the second A detection resistance 40a (an end opposite the second connection point P2) is connected to the other end of the second switch Sz.

Then, the one end of the first voltage-dividing circuit 30 (the one end of the first B detection resistance 30b opposite the first connection point P1) is connected to the negative-side power supply path L2 as described above. Moreover, the other end of the first voltage-dividing circuit 30 (the one end of the first A detection resistance 30a opposite the first connection point P1) is connected to the connection point P3 between the first switch Si and the second switch Sz and connected in series to the vehicle-side ground FG via the first switch Si. Thus, the first voltage-dividing circuit 30 is switched to the current-carrying state by turning on the first switch Si and the first voltage-dividing circuit 30 is switched to the current-blocked state by turning off the first switch Si.

Likewise, the one end of the second voltage-dividing circuit 40 (the one end of the second B detection resistance 40b opposite the second connection point P2) is connected to the negative-side power supply path L2. Moreover, the other end of the second voltage-dividing circuit 40 (the one end of the second A detection resistance 40a opposite the second connection point P2) is connected in series to, out of both ends of the second switch Sz, one end opposite the first switch Si (opposite the connection point P3) and connected in series to the vehicle-side ground FG via the second switch Sz and the first switch Si. Thus, the second voltage-dividing circuit 40 is switched to the current-carrying state by turning on both the first switch Si and the second switch Sz and the second voltage-dividing circuit 40 is switched to the current-blocked state by turning off any one of the first switch Si and the second switch Sz.

That is to say, the first voltage-dividing circuit 30 and the second voltage-dividing circuit 40 can be collectively disconnected from the vehicle-side ground FG to be switched to the current-blocked state by turning off the first switch Si. Moreover, the second voltage-dividing circuit 40 can be disconnected from the vehicle-side ground FG to be switched to the current-blocked state irrespective of the state of the first voltage-dividing circuit 30 by turning off the second switch Sz.

Moreover, both the first voltage-dividing circuit 30 and the second voltage-dividing circuit 40 can be switched to the current-carrying state by turning on both the first switch Si and the second switch Sz. Moreover, only the first voltage-dividing circuit 30 can be switched to the current-carrying state by turning on the first switch Si and turning off the second switch Sz.

The detection circuit 60 includes a first detection circuit 61 located on the first output line L11 and a second detection circuit 62 located on the second output line L12. The first detection circuit 61 includes a filter circuit or the like and outputs, out of signals inputted through the first output line L11, a denoised signal to the control device 70 as a signal from the first voltage-dividing circuit 30. Likewise, the second detection circuit 62 includes a filter circuit or the like and outputs, out of signals inputted through the second output line L12, a denoised signal to the control device 70 as a signal from the second voltage-dividing circuit 40.

The control device 70 consists mainly of a microcomputer including a CPU, a ROM, a RAM, an I/O, and the like and the CPU executes a program stored in the ROM to implement a variety of functions. It should be noted that the variety of functions may be implemented by an electronic circuit, which is hardware, or may be at least partly implemented by software, that is, a process performed on a computer. The control device 70 has a function to control the on-off states of the first switch Si and the second switch Sz of the switching unit 50, a function to detect current leakage, and the like. It should be noted that a switch controller having a function to control the on-off states of the variety of switches, and the like may be provided independently of the control device 70 to detect current leakage in combination with the control device 70.

In the meanwhile, the control device 70 estimates values of the insulation resistances Rp, Rn on based on the signals (divided voltage values) inputted from the first voltage-dividing circuit 30 and the second voltage-dividing circuit 40 and detects current leakage. Thus, in a case where there is an abnormality of the detection resistances 30a, 30b, 40a, 40b of the first voltage-dividing circuit 30 and the second voltage-dividing circuit 40 and a divided voltage value has an error, the accuracy of detection of current leakage is lowered. For example, a change in the values of the detection resistances 30a, 30b, 40a, 40b due to aging, contact failure, foreign matter involvement, breaking, short circuit, or the like leads to lowering of the accuracy of detection of current leakage. Accordingly, in the present embodiment, a characteristic determination, that is, a determination of whether there is an abnormality in the characteristics of the first voltage-dividing circuit 30 and the second voltage-dividing circuit 40, is to be performed. It should be noted that in the present embodiment, the characteristic determination is to be performed during current leakage detection so that being able to be performed at any time even while the vehicle is moving. A current leakage detection process will be described below in detail.

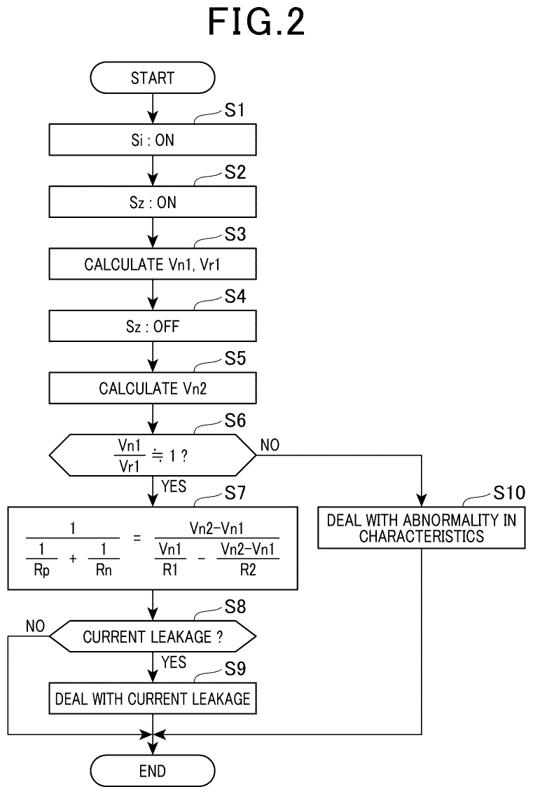

FIG. 2 illustrates a flow of the current leakage detection process. The current leakage detection process is to be performed by the control device 70 in a predetermined cycle (for example, every several tens ms).

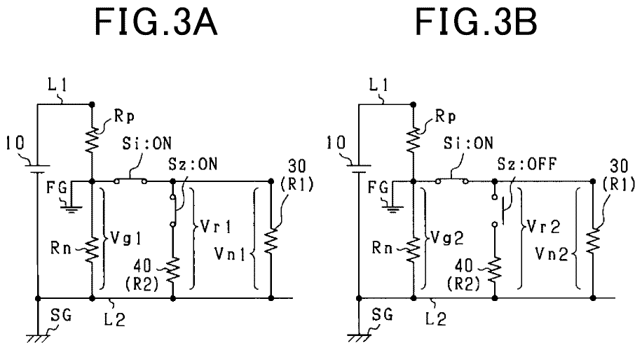

First, the control device 70 turns on the first switch Si (Step S1) and turns on the second switch Sz (Step S2). This puts both the first voltage-dividing circuit 30 and the second voltage-dividing circuit 40 into the current-carrying state as illustrated in a schematic diagram of FIG. 3A, consequently putting the first voltage-dividing circuit 30, the second voltage-dividing circuit 40, and the insulation resistance Rn into a state of being connected in parallel between the negative-side power supply path L2 and the vehicle-side ground FG.

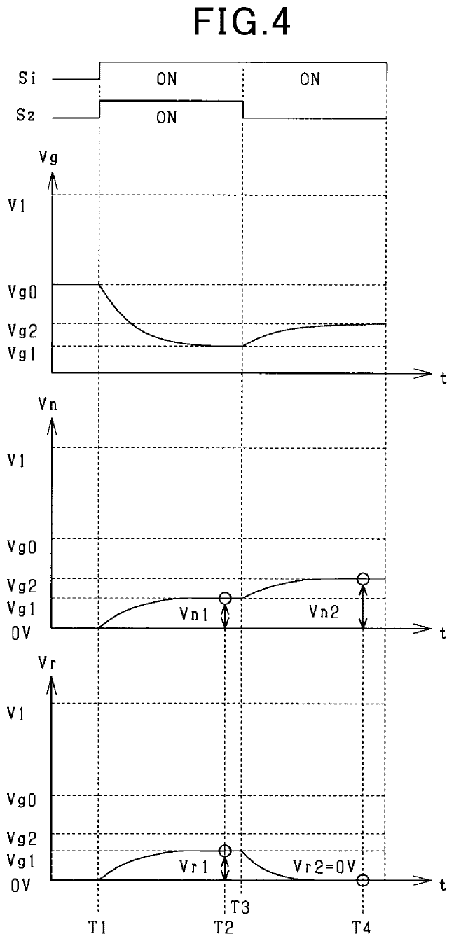

As illustrated in FIG. 4, the control device 70 waits at this time until the elapse of a predetermined duration of time (a time point T1 to a time point T2) from a timing when the first switch Si and the second switch Sz are both turned on (the time point T1) so that a signal becomes stable. The control device 70A then inputs a first divided voltage value αVn1 from the first voltage-dividing circuit 30 through the first detection circuit 61 at a timing when the predetermined duration of time elapses (the time point T2) (Step S3). At that timing (the time point T2), the control device 70 inputs a second divided voltage value βVr1 from the second voltage-dividing circuit 40 through the second detection circuit 62 (Step S3).

It should be noted that in FIG. 4, an end-to-end voltage of the insulation resistance Rn corresponds to Vg and Vg0 corresponds to an end-to-end voltage of the insulation resistance Rn when the first voltage-dividing circuit 30 and the second voltage-dividing circuit 40 are both put in the current-blocked state. Moreover, as illustrated in FIG. 3A, Vg1 corresponds to an end-to-end voltage of the insulation resistance Rn when the first voltage-dividing circuit 30 and the second voltage-dividing circuit 40 are both put in the current-carrying state. Moreover, as illustrated in FIG. 3B, Vg2 corresponds to an end-to-end voltage of the insulation resistance Rn when the first voltage-dividing circuit 30 is put in the current-carrying state and the second voltage-dividing circuit 40 is put in the current-blocked state.

The first divided voltage value corresponds to a value αVn1 given by multiplying the end-to-end voltage of the first voltage-dividing circuit 30 when the first voltage-dividing circuit 30 and the second voltage-dividing circuit 40 are both put in the current-carrying state by the voltage-dividing ratio α. The second divided voltage value corresponds to a value βVr1 given by multiplying the end-to-end voltage of the second voltage-dividing circuit 40 when the first voltage-dividing circuit 30 and the second voltage-dividing circuit 40 are both put in the current-carrying state by the voltage-dividing ratio β.

Accordingly, in Step S3, the control device 70 calculates the end-to-end voltage (hereinafter, referred to as detected voltage Vn1) of the first voltage-dividing circuit 30 by dividing the inputted first divided voltage value αVn1 by the voltage-dividing ratio α. Likewise, in Step S3, the control device 70 calculates the end-to-end voltage (hereinafter, referred to as detected voltage Vr1) of the second voltage-dividing circuit 40 by dividing the inputted second divided voltage value βVn1 by the voltage-dividing ratio β. It should be noted that the detected voltages Vn1, Vr1 may be calculated in later-described Step S6.

Next, the control device 70 turns off the second switch Sz while the first switch Si is on (Step S4). This puts the second voltage-dividing circuit 40 into the current-blocked state while the first voltage-dividing circuit 30 is in the current-carrying state as illustrated in FIG. 3B, consequently putting the first voltage-dividing circuit 30 and the insulation resistance Rn into a state of being connected in parallel between the negative-side power supply path L2 and the vehicle-side ground FG.

As illustrated in FIG. 4, the control device 70 waits at this time until the elapse of a predetermined duration of time (a time point T3 to a time point T4) from a timing when the second switch Sz is switched off (the time point T3) so that a signal becomes stable. Then, the control device 70 inputs a third divided voltage value αVn2 from the first voltage-dividing circuit 30 through the first detection circuit 61 at a timing when the predetermined duration of time elapses (the time point T4) (Step S5). Moreover, in Step S5, the control device 70 calculates the end-to-end voltage (hereinafter, referred to as detected voltage Vn2) of the first voltage-dividing circuit 30 by dividing the inputted third divided voltage value αVn2 by the voltage-dividing ratio α. It should be noted that the detected voltage Vn2 may be calculated in later-described Step S7.

After that, the control device 70 performs the characteristic determination of whether there is an abnormality of the first voltage-dividing circuit 30 and the second voltage-dividing circuit 40 (Step S6). Specifically, it is determined whether there is an abnormality of the first voltage-dividing circuit 30 and the second voltage-dividing circuit 40 by determining whether Vn1/Vr1 is approximately one. That is to say, it is determined whether the value of Vn1/Vr1 falls within a predetermined range close to one (1−x<Vn1/Vr1<1+y:x and y are values set in consideration of a required calculation accuracy). There is determined to be no abnormality in response to the value of Vn1/Vr1 falling within the predetermined range close to one, whereas there is determined to be an abnormality in response to the value not falling within the predetermined range.

It should be noted that the control device 70 may perform the characteristic determination by determining whether Vn1 and Vr1 are substantially the same in value. That is to say, Vn1 and Vr1 are compared and it is determined whether a difference therebetween is equal to or less than a predetermined determination value (a value set in consideration of the required calculation accuracy). Then, there is determined to be no abnormality in a case where the difference is equal to or less than the determination value, whereas there is determined to be an abnormality in a case where the value is more than the determination value.

In response to a positive result of the determination (in response to no abnormality), the control device 70 computes an insulation resistance based on Vn1, Vn2 (Step S7) and determines current leakage based on whether that value is equal to or less than a threshold for current leakage determination (Step S8). Description will be given of Step S7.

Vn1 is the end-to-end voltage of the first voltage-dividing circuit 30 in a state where the first voltage-dividing circuit 30, the second voltage-dividing circuit 40, and the insulation resistance Rn are connected in parallel between the negative-side power supply path L2 and the vehicle-side ground FG as illustrated in FIG. 3A and thus can be represented as Expression (1). Incidentally, it is assumed that a value of a resistance (a combined resistance) of the first voltage-dividing circuit 30 is R1 and a value of a resistance (a combined resistance of the second voltage-dividing circuit 40 is R2. An end-to-end voltage of the assembled battery 10 is V1.

$$\begin{matrix}[ Math . 1 ] & \\ V n 1 = \frac{\frac{V 1}{R p}}{\frac{1}{R 1} + \frac{1}{R 2} + \frac{1}{R p} + \frac{1}{R n}} & ( 1 )\end{matrix}$$

Moreover, Vn2 is the end-to-end voltage of the first voltage-dividing circuit 30 in a state where the first voltage-dividing circuit 30 and the insulation resistance Rn are connected in parallel between the negative-side power supply path L2 and the vehicle-side ground FG as illustrated in FIG. 3B and thus can be represented as Expression (2).

$$\begin{matrix}[ Math . 2 ] & \\ V n 2 = \frac{\frac{V 1}{R p}}{\frac{1}{R 1} + \frac{1}{R p} + \frac{1}{R n}} & ( 2 )\end{matrix}$$

Then, the insulation resistances Rp, Rn are obtainable as represented by Expressions (3) to (4) from Expressions (1) to (2). Moreover, a combined arithmetic expression (Expression (5)) of the insulation resistances Rp, Rn is obtainable by eliminating the inter-terminal voltage V1 of the assembled battery 10.

$$[ Math . 3 ]$$

$$Rp = \frac{V 1 \cdot ( Vn 2 - V n 1 )}{Vn 2 \cdot Vn 1} \cdot R 1 \qquad ( 3 )$$

$$Rn = \frac{V 1 \cdot ( Vn 2 - V n 1 )}{\frac{( V 1 - Vn 2 ) \cdot Vn 1}{R 1} - \frac{V 1 \cdot ( Vn 2 - V n 1 )}{R 2}} \qquad ( 4 )$$

$$\frac{1}{\frac{1}{Rp} + \frac{1}{R n}} = \frac{Vn 2 - Vn 1}{\frac{Vn 1}{R 1} - \frac{Vn 2 - V n 1}{R 2}} \qquad ( 5 )$$

In Step S8, the control device 70 detects current leakage based on whether a value of the combined arithmetic expression of the insulation resistances Rp, Rn represented by Expression (5) is equal to or less than a preset threshold Th for current leakage determination. It should be noted that in Step S8, the control device 70 may detect current leakage based on whether the insulation resistance Rp computed from Expression (3) and the insulation resistance Rn computed from Expression (4) are equal to or less than set thresholds Rp0, Rn0 for current leakage determination, respectively.

In response to a positive result of the determination in Step S8 (in response to current leakage being detected), the control device 70 performs a process for dealing with current leakage (Step S9) and terminates the current leakage detection process. The process for dealing with current leakage is, for example, a process for informing an external device of current leakage to warn about it. In contrast, in response to a negative result of the determination in Step S8 (in response to no current leakage being detected), the control device 70 directly terminates the current leakage detection process as the first voltage-dividing circuit 30 and the second voltage-dividing circuit 40 are considered to be normal.

In contrast, in response to a negative result of the determination in Step S6 (in response to there being an abnormality in characteristics), the control device 70 performs a process for dealing with an abnormality of the voltage-dividing circuits 30, 40 as the first voltage-dividing circuit 30 or the second voltage-dividing circuit 40 is considered to have an abnormality (Step S10) and terminates the current leakage detection process. The process for dealing with an abnormality of the voltage-dividing circuits 30, 40 is, for example, a process for informing an external device of the abnormality to warn about the impossibility of current leakage detection, or the like.

Description will be made below on effects of the first embodiment.

(1) In a first input step (corresponding to Steps S1 to S3), the control device 70 switches on both the first switch Si and the second switch Sz and inputs the first divided voltage value αVn1 and the second divided voltage value βVr1. After that, in a second input step (corresponding to Steps S4 to S5), the control device 70 switches off the second switch Sz and inputs the third divided voltage value &Vn2.

The control device 70 then performs a characteristic determination step (corresponding to Step S6) based on the first divided voltage value αVn1 and the second divided voltage value βVr1. Specifically, the control device 70 performs the characteristic determination by calculating the detected voltages Vn1, Vr1 from the first divided voltage value αVn1 and the second divided voltage value βVr1 and comparing the detected voltage Vn1 and the detected voltage Vr1.

The control device 70 also performs a current leakage detection step (corresponding to Steps S7 to S8) based on the first divided voltage value αVn1 and the third divided voltage value αVn2. Specifically, the control device 70 detects current leakage by calculating the detected voltages Vn1, Vn2 from the first divided voltage value αVn1 and the third divided voltage value αVn2 and computing the insulation resistances Rn, Rp based on Expressions (3), (4) or calculating a value of the combined arithmetic expression of the insulation resistances Rn, Rp represented by Expression (5) and making a comparison with the threshold for current leakage determination.

It is thus possible to input the first divided voltage value and the second divided voltage value necessary for performing the characteristic determination while the first input step and the second input step (Steps S1 to S5) necessary for the current leakage detection are performed, more specifically, while the first input step (Steps S1 to S3) is performed. This eliminates the necessity of switching the switching unit 50 to make time for measurement solely in order to acquire the first divided voltage value and the second divided voltage value necessary for the characteristic determination, enabling the current leakage detection and the characteristic determination to be efficiently performed. The characteristic determination can thus be performed at the same time as the current leakage detection, which makes it possible to determine an abnormality of the voltage-dividing circuits 30, 40 at any time, for example, while the vehicle is moving.

(2) In a case where a value of the combined arithmetic expression of the insulation resistances Rn, Rp represented by Expression (5) is to be calculated to detect current leakage, it is not necessary to measure the inter-terminal voltage V1 of the assembled battery 10. This eliminates the necessity of taking a measurement error of the inter-terminal voltage V1 into consideration, so that the accuracy of current leakage detection is improved.

(3) The one end of the first voltage-dividing circuit 30 is connected to the negative-side power supply path L2, whereas the other end thereof is connected to the connection point P3 between the first switch Si and the second switch Sz and connected in series to the vehicle-side ground FG via the first switch Si. Moreover, the one end of the second voltage-dividing circuit 40 is connected to the negative-side power supply path L2, whereas the other end thereof is connected in series to, out of both ends of the second switch Sz, the one end on the side not connected to the first switch Si (opposite the connection point P3) and connected in series to the vehicle-side ground FG via the second switch Sz and the first switch Si. The use of such a circuit configuration makes it possible to set the number of switches to be used in the current leakage detection device 20 at two. In particular, in a case where complete isolation between the vehicle-side ground FG and the negative-side power supply path L2 (and the positive-side power supply path L1) is desired, a high-withstand-voltage mechanical relay is preferred. However, since it is sufficient that only the first switch Si, which enables collectively putting the first voltage-dividing circuit 30 and the second voltage-dividing circuit 40 into the current-blocked state, is mechanically relayed, it is possible to reduce the number of mechanical relays.

### Second Embodiment

A part of the configuration of the first embodiment may be changed as follows. It should be noted that a circuit configuration of the current leakage detection device 20 is similar to that of the first embodiment and the description thereof is omitted, accordingly.

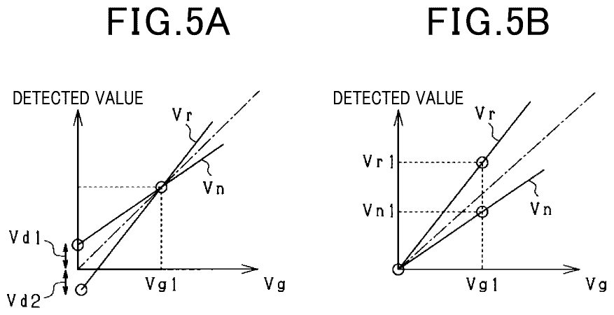

In the first embodiment, in a case where the characteristic determination is to be performed with use of the first divided voltage value and the second divided voltage value, an error based on the circuit characteristics of each of the voltage-dividing circuits 30, 40 is likely to lead to an erroneous determination. The above will be described in detail. It is assumed that due to the circuit characteristics of the first voltage-dividing circuit 30, a detected voltage Vn calculated based on the divided voltage value αVn therefrom has an error Vd1, while due to the circuit characteristics of the second voltage-dividing circuit 40, the detected voltage Vr calculated based on the divided voltage value BVr therefrom has an error Vd2 as illustrated in FIG. 5A.

In this case, under ordinary circumstances (in a case where there is no error, see FIG. 5B), the characteristics should be considered to be abnormal as the detected voltage Vn1 and the detected voltage Vr1 fail to match. However, there is a possibility that the characteristics are determined to be normal as the detected voltage Vn1 and the detected voltage Vr1 are caused to match due to the errors Vd1, Vd2 as illustrated in FIG. 5A. As seen from the above, there is a possibility that the characteristic determination is erroneously performed due to the errors Vd1, Vd2 attributed to the characteristics of the voltage-dividing circuits 30, 40.

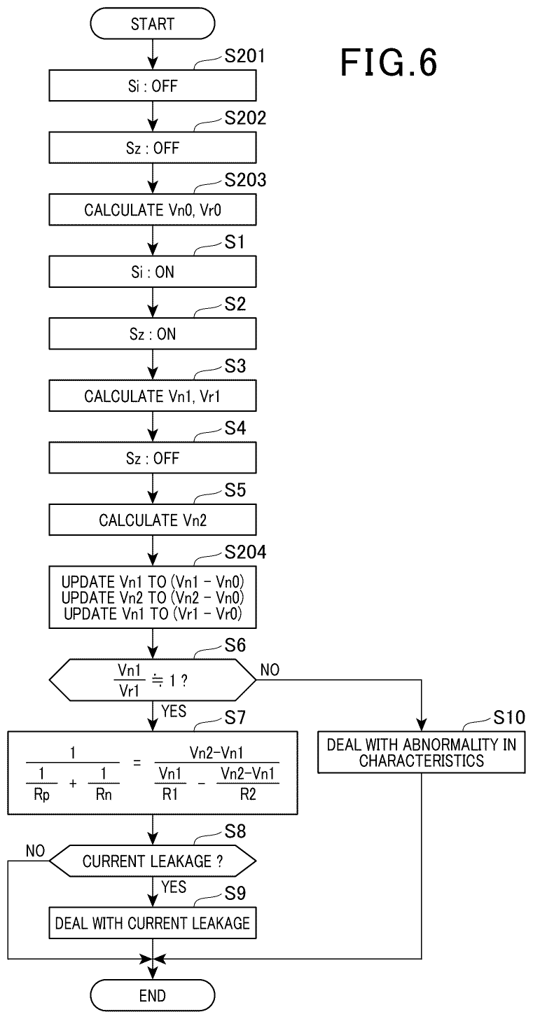

Accordingly, in the second embodiment, the current leakage detection process is partly changed so as to correct a deviation due to the errors Vd1, Vd2. Description will be given of a current leakage detection process of the second embodiment with reference to FIG. 6.

In performing the current leakage detection process, the control device 70 first turns off the first switch Si (Step S201) and turns off the second switch Sz (Step S202). This puts both the first voltage-dividing circuit 30 and the second voltage-dividing circuit 40 into the current-blocked state.

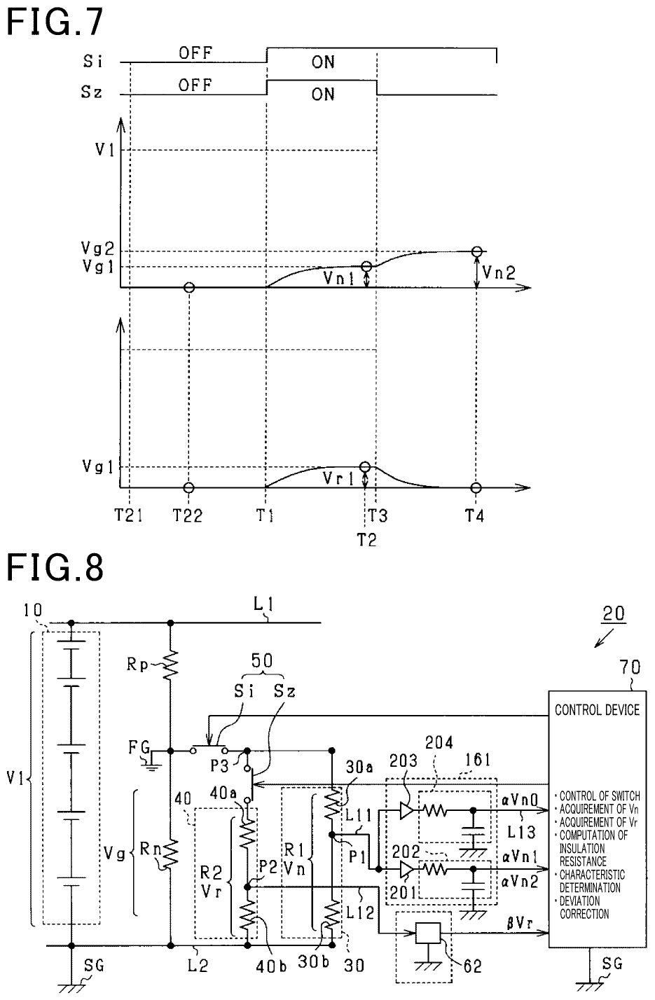

As illustrated in FIG. 7, the control device 70 waits at this time until the elapse of a predetermined duration of time (a time point T21 to a time point T22) from a timing when the first switch Si and the second switch Sz are both switched off (the time point T21) so that a signal becomes stable. The control device 70 then inputs an output value αVn0 from the first voltage-dividing circuit 30 through the first detection circuit 61 at a timing when the predetermined duration of time elapses (the time point T22) (Step S203). At that timing (the time point T22), the control device 70 inputs an output value βVr0 from the second voltage-dividing circuit 40 through the second detection circuit 62 (Step S203).

Then, in Step S203, the control device 70 calculates a first initial value Vn0, which is an end-to-end voltage of the first voltage-dividing circuit 30 in the current-blocked state, by dividing the inputted output value «Vn0 by the voltage-dividing ratio α. Likewise, in Step S203, the control device 70 calculates a second initial value Vr0, which is an end-to-end voltage of the second voltage-dividing circuit 40 in the current-blocked state, by dividing the inputted output value βVr0 by the voltage-dividing ratio β. It should be noted that in an ideal state where there is no error, the first initial value Vn0 and the second initial value Vr0 are zero, whereas in a case where there is an error, the initial values Vn0, Vr0 correspond to the errors Vd1, Vd2, respectively. It should be noted that the initial values may be calculated in later-described Step S204.

After that, Steps S1 to S5 are performed as in the first embodiment. After Step S5 is performed, the control device 70 performs a correction step to correct an error of the circuit characteristics of the voltage-dividing circuits 30, 40 based on the first initial value Vn0 and the second initial value Vr0 (Step S204). In details, in Step S204, the control device 70 corrects a deviation of the first voltage-dividing circuit 30 based on the first initial value Vn0 acquired in an initial value acquirement step (corresponding to Steps S201 to S203). That is to say, the control device 70 updates a value (Vn1-Vn0) given by subtracting the first initial value Vn0 from the detected voltage Vn1 as a corrected detected voltage Vn1. Likewise, the control device 70 updates a value (Vn2-Vn0) given by subtracting the first initial value Vn0 from the detected voltage Vn2 as a corrected detected voltage Vn2.

The control device 70 also corrects a deviation of the second voltage-dividing circuit 40 based on the second initial value Vr0 acquired in the initial value acquirement step. That is to say, the control device 70 updates a value (Vr1-Vr0) given by subtracting the second initial value Vr0 from the detected voltage Vr1 as a corrected detected voltage Vr1. After that, the control device 70 performs Step S6 and the subsequent steps based on the corrected (updated) detected voltages Vn1, Vn2, Vr1 as in the first embodiment.

The second embodiment produces the following effect in addition to Effects (1) to (3) of the first embodiment.

(4) The control device 70 puts both the first voltage-dividing circuit 30 and the second voltage-dividing circuit 40 into the current-blocked state and acquires the first initial value Vn0 and the second initial value Vr0 respectively corresponding to errors of the circuit characteristics of the first voltage-dividing circuit 30 and the second voltage-dividing circuit 40. The control device 70 then corrects deviations of the detected voltages Vn1, Vn2, Vr1 based on the initial values Vn0, Vr0 of the first voltage-dividing circuit 30 and the second voltage-dividing circuit 40 and performs, after the updating, the characteristic determination and the current leakage detection. This makes it possible to improve the accuracies of the characteristic determination and the current leakage detection.

### Third Embodiment

A part of the configuration of the second embodiment may be changed as follows. The description is as follows.

In the current leakage detection device 20, noise is removed by inputting a divided voltage value from the first voltage-dividing circuit 30 through the first detection circuit 61 as illustrated in FIG. 1.

In the meanwhile, in a case where a divided voltage value is to be acquired from the first voltage-dividing circuit 30 in the current-carrying state with the first switch Si turned on, a common noise of the vehicle-side ground FG has an influence. Since the common noise of the vehicle-side ground FG is large, a filter circuit capable of removing the noises need to be used in the first detection circuit 61 and the second detection circuit 62. For example, in a case where the filter circuits of the first detection circuit 61 and the second detection circuit 62 are in a form of an RC low-pass filter, it is necessary to increase a value of a resistance and a capacity of the capacitor. It should be noted that the same applies to a case where a divided voltage value is to be inputted from the second voltage-dividing circuit 40 in the current-carrying state through the second detection circuit 62.

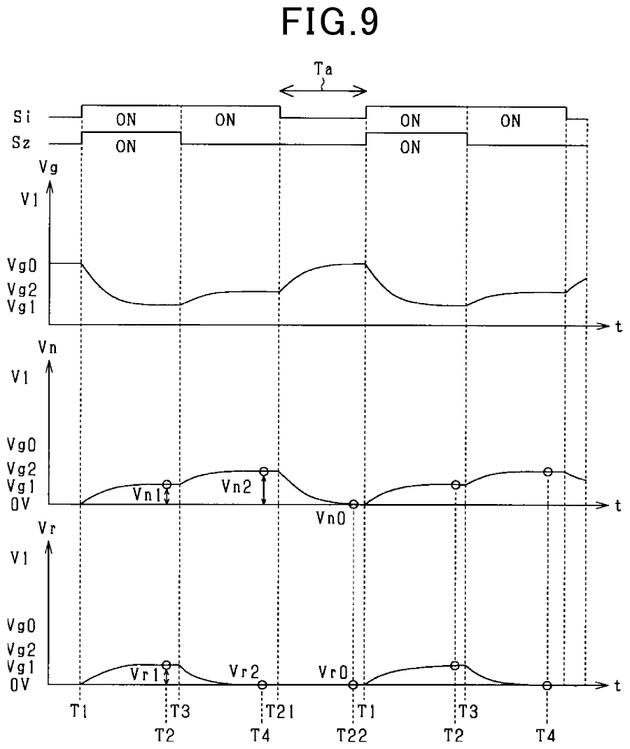

However, in a case where a heavy filter circuit with increased value of a resistance and capacity of a capacitor is used, a time constant is also increased, which leads to a concern that time required to acquire the initial value is increased in the second embodiment. In more detail, in the second embodiment, the third divided voltage value αVn2 is acquired from the first voltage-dividing circuit 30 (the time point T4) and then the first switch Si is turned off in order to acquire the initial value (Step S201) as illustrated in FIG. 9.

At this time, in a case where a heavy filter circuit with a large time constant is used in the first detection circuit 61, it is necessary to increase standby time (T21 to T22) from a time point T21 at which the first switch Si is turned off to a time point T22 at which the output value αVn0 is acquired. That is to say, standby time before the voltage signal decreases sufficiently and reaches a sufficiently stable value is increased. This increases time Ta required to acquire the initial value.

Accordingly, in a third embodiment, a part of the first detection circuit 61 of the current leakage detection device 20 is changed as illustrated in FIG. 8. The explanation is as follows.

As illustrated in FIG. 8, a first detection circuit 161 of the third embodiment includes a first buffer 201, a heavy filter circuit 202 with a large time constant, a second buffer 203, and a light filter circuit 204 with a smaller time constant than the heavy filter circuit 202. The heavy filter circuit 202 and the light filter circuit 204 are each an RC low-pass filter and a value of a resistance and a capacity of a capacitor of the heavy filter circuit 202 are large as compared with those of the light filter circuit 204.

The first buffer 201 and the heavy filter circuit 202 are connected in series and located on the first output line L11. The control device 70 inputs the first divided voltage value αVn1 and the third divided voltage value αVn2 through the first buffer 201 and the heavy filter circuit 202. It should be noted that the first buffer 201 inputs a signal from the first voltage-dividing circuit 30 at high impedance and outputs it to the heavy filter circuit 202 at low impedance.

Then, the second buffer 203 and the light filter circuit 204 are connected in series and connected to be parallel with respect to a series circuit including the first buffer 201 and the heavy filter circuit 202. In detail, a branched line L13 branched from the first output line L11 is provided between the first voltage-dividing circuit 30 (the connection point P3 thereof) and the first buffer 201. The branched line L13 is provided with the second buffer 203 and the light filter circuit 204 and the control device 70 inputs the output value α Vn0 through the second buffer 203 and the light filter circuit 204.

The second detection circuit 62 is similar in configuration to that of the first embodiment and, for example, the second detection circuit 62 is in a form of a series circuit including the first buffer 201 and the heavy filter circuit 202.

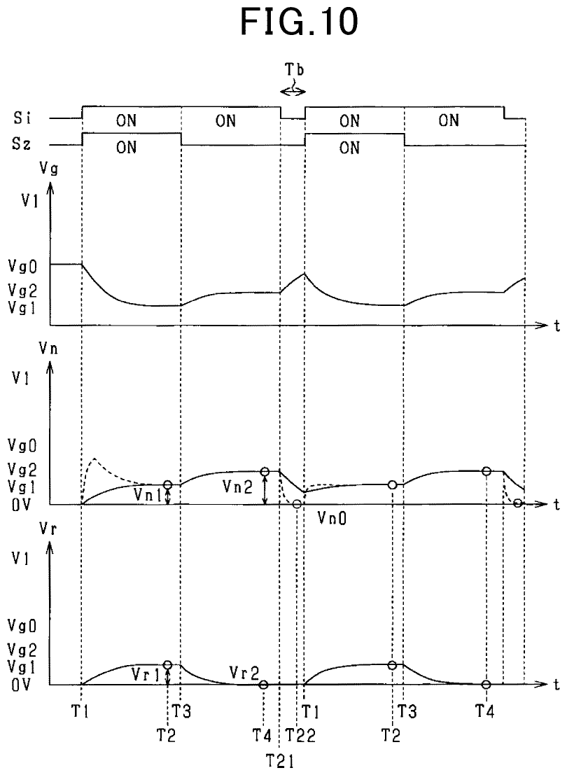

Effects of the above-described configuration will be described based on FIG. 9 and FIG. 10.

FIG. 9 illustrates a transition of detected voltages Vn, Vr in a case where no light filter circuit 204 is used. As illustrated in FIG. 9, from the time point T21 to the time point T22, the output value αVn0, which is a basis of the initial value Vn0, is inputted through the heavy filter circuit 202, so that it takes time for the detected voltage Vn to sufficiently decrease and reach a stable value. This increases time Ta required to acquire the initial value.

Next, Description will be given of a transition of the detected voltages Vn, Vr according to the third embodiment with reference to FIG. 10. In FIG. 10, a transition of the detected voltage Vn calculated based on a signal inputted through the heavy filter circuit 202 is represented by a solid line and a transition of the detected voltage Vn calculated based on a signal inputted through the light filter circuit 204 is represented by a broken line.

As represented by the broken line in FIG. 10, the input through the light filter circuit 204 with a small time constant leads to a prompt drop of the detected voltage Vn. This makes it possible to shorten the standby time (T21 to T22) before the stable value is reached in a case where the input is performed through the light filter circuit 204 with a small time constant as compared with in a case where the input is performed through the heavy filter circuit 202. Thus, time Tb required to acquire the initial value is increased.

It should be noted that in the third embodiment, the second detection circuit 62 includes the heavy filter circuit 202 as in the first embodiment. However, it is possible to afford to take sufficient time before the output value βVr0, which is a basis of the second initial value Vr0, is inputted (the time point T22) after the second switch Sz is turned off (the time point T3) as shown by the detected voltage Vr in FIG. 10. This eliminates the necessity of providing the light filter circuit 204 as in the first detection circuit 161. However, there is no problem even if the second detection circuit 62 is configured similarly to the first detection circuit 161.

The third embodiment produces the following effect in addition to Effects (1) to (3) of the first embodiment and Effect (4) of the second embodiment.

(5) In a case where a signal from the first voltage-dividing circuit 30 is inputted with a current-carrying between the negative-side power supply path L2 and the vehicle-side ground FG through the first voltage-dividing circuit 30, it is necessary to reduce an influence of a common noise from the vehicle-side ground FG. Accordingly, in a case where the first voltage-dividing circuit 30 is in the current-carrying state, the control device 70 needs to input a signal through the heavy filter circuit 202 with a large time constant. However, in a case where a signal is inputted through the heavy filter circuit 202, it takes time before the signal becomes stable due to the large time constant. Accordingly, in a case where the first voltage-dividing circuit 30 is in the current-blocked state, the output value αVn0 is to be inputted through the light filter circuit 204 with a small time constant. That makes it possible to shorten the time before the output value «Vn0, which is a basis of the initial value Vn0, is acquired (Ta→Tb). It should be noted that the output value αVn0 is to be inputted from the first voltage-dividing circuit 30 with a current blocked between the negative-side power supply path L2 and the vehicle-side ground FG, so that there is no concern that a common noise from the vehicle-side ground FG has an influence during the input of the output value αVn0.

### Fourth Embodiment

The configurations of the first embodiment to the third embodiment may be partly changed as follows. With reference to the configuration of the first embodiment, a difference therefrom will be described in a fourth embodiment.

In the first embodiment, in a case where the current leakage detection is to be performed based on the combined arithmetic expression (Expression (5)) of the insulation resistances Rp, Rn, the lowering of the insulation resistances Rp, Rn is likely to temporarily increase an influence of a circuit tolerance because of the combined arithmetic expression. The above will be described in detail.

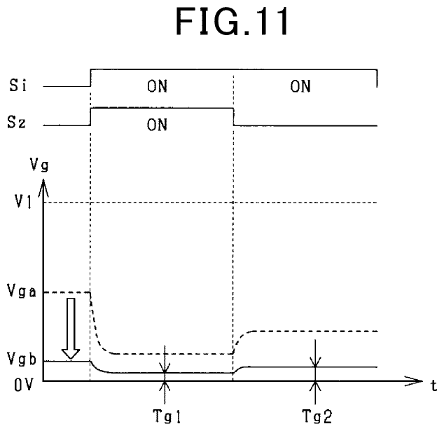

As illustrated in FIG. 11, the lowering of the insulation resistance Rn leads to a decrease in the end-to-end voltage Vg of the insulation resistance Rn is decreased (Vga→Vgb). This also leads to a decrease in the end-to-end voltage Vg1 of the insulation resistance Rn with the first voltage-dividing circuit 30 and the second voltage-dividing circuit 40 both being in the current-carrying state and the end-to-end voltage Vg2 of the insulation resistance Rn with the first voltage-dividing circuit 30 being in the current-carrying state and the second voltage-dividing circuit 40 being in the current-blocked state. As a result, the detected voltages Vn1, Vn2 are also decreased to be close to zero.

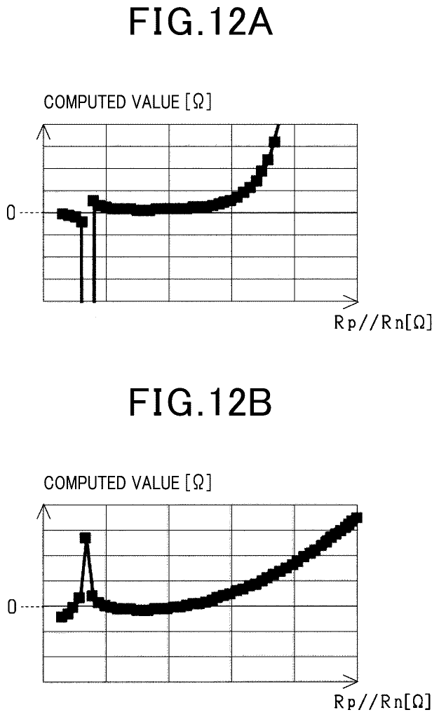

With the detected voltages Vn1, Vn2 being close to zero, the influence of the circuit tolerance is relatively increased. Thus, there is a possibility that the detected voltages Vn1, Vn2 become equal or the detected voltage Vn1 exceeds the detected voltage Vn2 with a magnitude relationship therebetween inverted. In this case, a value diverges (becomes unstable) as illustrated in FIG. 12, which makes it impossible to normally obtain a value or perform a normal determination.

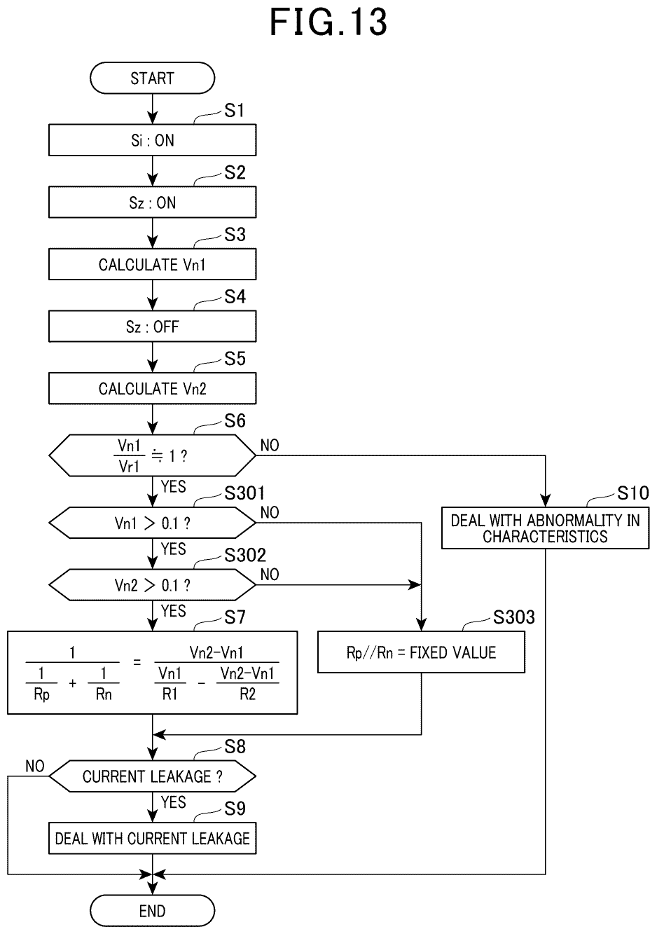

Accordingly, a current leakage detection process according to the fourth embodiment is added with a process for reducing the influence of the circuit tolerance or the like in response to a sufficient decrease in the detected voltages Vn1, Vn2 as illustrated in FIG. 13. The explanation is as follows.

After the process in Step S6, the control device 70 determines whether the detected voltage Vn1 is larger than a first threshold TL1 (Step S301). The first threshold TL1 is set at, for example, any value selected by taking account of the circuit tolerance or the like, which is 0.1 V in FIG. 13. In response to a positive result of the determination, that is, in response to the detected voltage Vn1 exceeding the first threshold TL1, the control device 70 determines whether the detected voltage Vn2 exceeds the second threshold TL2 (Step S302). The second threshold TL2 is set at, for example, any value selected by taking account of the circuit tolerance or the like, which is 0.1 V in FIG. 13. It should be noted that the first threshold TL1 and the second threshold TL2 may be the same value or different values.

In response to a positive result of the determination in Step S302, as an accurate determination using the value calculated by Expression (5) is considered to be possible, the control device 70 performs the process in Step S7 and the subsequent steps as in the first embodiment.

In contrast, in response to a negative result of the determination in Step S301 or Step S302, the control device 70 sets a fixed value as the value of the combined arithmetic expression of the insulation resistances Rp, Rn (Step S303). The fixed value, which is a value indicating that a current is leaking, is set in accordance with required specifications of the insulation resistances Rp, Rn.

After Step S303, the control device 70 performs Step S8 to detect current leakage. It should be noted that in a case where the fixed value is set in Step S303, current leakage is determined to always be present.

The fourth embodiment produces the following effect.

(6) If the insulation resistances Rp, Rn are decreased and the detected voltages Vn1, Vn2 become close to zero, the influence of the circuit tolerance or the like is increased, which makes the value of the combined arithmetic expression of the insulation resistances Rp, Rn likely to be unstable. Accordingly, the detected voltage Vn1 equal to or less than the first threshold TL1 or the detected voltage Vn2 equal to or less than the second threshold TL2 is to be detected as current leakage instead of computing the value of the combined arithmetic expression of the insulation resistances Rp, Rn. This makes it possible to accurately detect current leakage without the influence of the circuit tolerance.

### Modification Examples

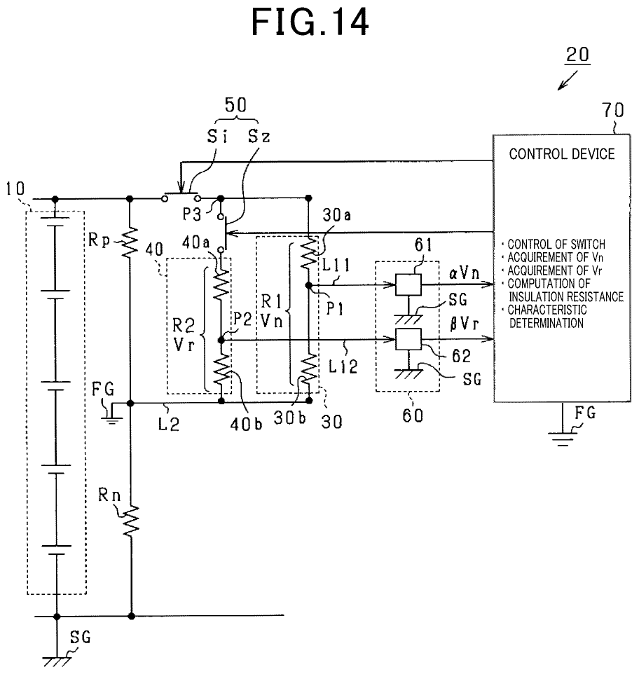

Description will be given of modification examples in which the above embodiments are partly changed.
In the above-described embodiments, the detection of current leakage and the process to deal with the current leakage are to be performed by the control device 70 but may be performed by an external device. In that case, the control device 70 only has to calculate and send the values of the insulation resistances Rp, Rn.
In the above-described embodiments, the current leakage detection device 20 is connected to between the negative-side power supply path L2 and the vehicle-side ground FG but may be connected to between the positive-side power supply path L1 and the vehicle-side ground FG as illustrated in FIG. 14. In more detail, the first voltage-dividing circuit 30 illustrated in a modification example in FIG. 14, which is connected to a side of the positive-side power supply path L1 at one end and connected to a side of the vehicle-side ground FG at the other end, is configured to divide a voltage between the positive-side power supply path L1 and the vehicle-side ground FG (the end-to-end voltage of the first voltage-dividing circuit 30) at the voltage-dividing ratio α. Then, the first A detection resistance 30a illustrated in FIG. 14 is connected to the side of the positive-side power supply path L1 and the first B detection resistance 30b is connected to the side of the vehicle-side ground FG.

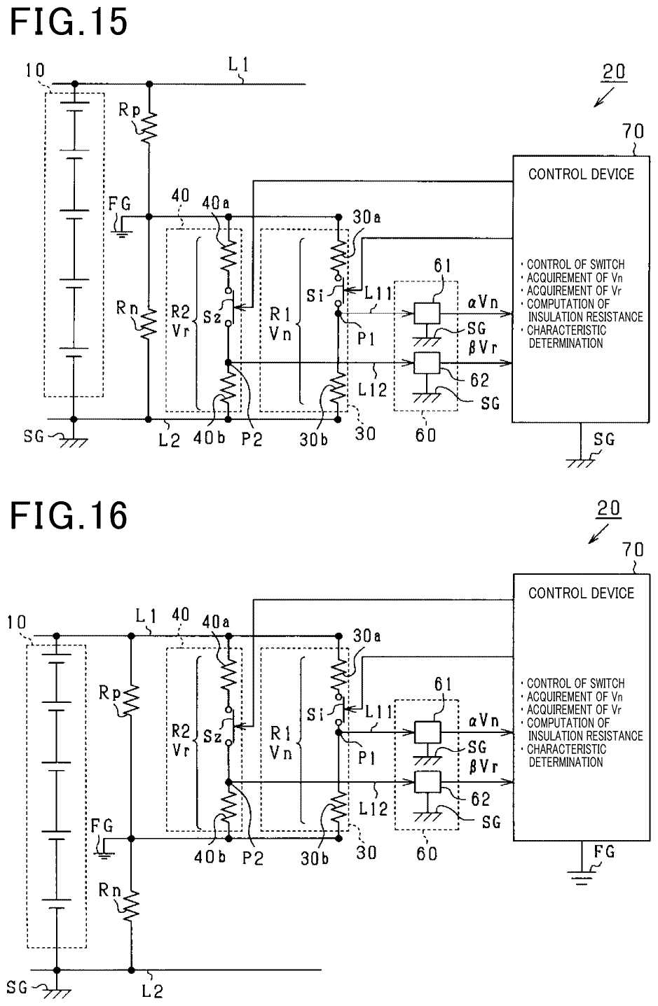

Moreover, the second voltage-dividing circuit 40 illustrated in FIG. 14, which is connected to a side of the positive-side power supply path L1 at one end and connected to a side of the vehicle-side ground FG at the other end, is configured to divide a voltage between the positive-side power supply path L1 and the vehicle-side ground FG (the end-to-end voltage of the second voltage-dividing circuit 40) at the voltage-dividing ratio β. Then, the second A detection resistance 40a illustrated in FIG. 14 is connected to the side of the positive-side power supply path L1 and the second B detection resistance 40b is connected to the side of the vehicle-side ground FG. Moreover, the first switch Si illustrated in FIG. 14 is connected to the positive-side power supply path L1 at one end and connected in series to one end of the second switch Sz at the other end. Moreover, with the assumption that the vehicle-side ground FG is a reference potential, the control device 70 inputs signals from the first voltage-dividing circuit 30 and the second voltage-dividing circuit 40.
In the above-described embodiments, the locations of the first switch Si and the second switch Sz may be changed as illustrated in FIG. 15. That is to say, the first switch Si is connected to between the first connection point P1 and the first A detection resistance 30a and configured to be able to switch between the current-carrying state and the current-blocked state between the first connection point P1 and the first A detection resistance 30a. The second switch Sz is connected to between the second connection point P2 and the second A detection resistance 40a and configured to be able to switch between the current-carrying state and the current-blocked state between the second connection point P2 and the second A detection resistance 40a. In this case, the control device 70 does not need to include a differential amplifier circuit. It should be noted that the first switch Si may be changed in location between the first connection point P1 and the vehicle-side ground FG as long as being configured to be able to switch the current-carrying state between the first connection point P1 and the first A detection resistance 30a. Likewise, the second switch Sz may be changed in location between the second connection point P2 and the vehicle-side ground FG as long as being configured to be able to switch the current-carrying state between the second connection point P2 and the second A detection resistance 40a.
In the above-described embodiment, while connected to between the positive-side power supply path L1 and the vehicle-side ground FG, the first switch Si and the second switch Sz may be changed in location as illustrated in FIG. 16.

As illustrated in FIG. 16, the first A detection resistance 30a of this modification example is connected to the side of the positive-side power supply path L1, the first B detection resistance 30b is connected to the side of the vehicle-side ground FG, the second A detection resistance 40a is connected to the side of the positive-side power supply path L1, and the second B detection resistance 40b is connected to the side of the vehicle-side ground FG. The first switch Si is connected to between the first connection point P1 and the first A detection resistance 30a and configured to be able to switch between the current-carrying state and the current-blocked state between the first connection point P1 and the first A detection resistance 30a. The second switch Sz is then connected to between the second connection point P2 and the second A detection resistance 40a and configured to be able to switch between the current-carrying state and the current-blocked state between the second connection point P2 and the second A detection resistance 40a. Moreover, the control device 70 is connected to the vehicle-side ground and measures a signal inputted with the assumption that the vehicle-side ground FG is a reference of potential. In this case, the control device 70 does not need to include a differential amplifier circuit. It should be noted that the first switch Si may be changed in location between the first connection point P1 and the positive-side power supply path L1 as long as being configured to be able to switch the current-carrying state between the first connection point P1 and the first A detection resistance 30a. Likewise, the second switch Sz may be changed in location between the second connection point P2 and the positive-side power supply path L1 as long as being configured to be able to switch the current-carrying state between the second connection point P2 and the second A detection resistance 40a.
In the above-described first embodiment, the above-described fourth embodiment, or a modification example thereof, the first switch Si may be omitted as long as a design in which vehicle insulation is not affected even though a value of the resistance value R1 of the first voltage-dividing circuit 30 is equivalent to or more than the insulation resistances Rp, Rn is possible. In this case, the switching unit corresponds to the second switch Sz. Such a configuration causes the first voltage-dividing circuit 30 to be always in the current-carrying state, so that it is not possible to correct a circuit error with the first voltage-dividing circuit 30 put in the current-blocked state as described in the second embodiment and the third embodiment. However, since the first switch Si is omitted, it is possible to achieve the current leakage detection and the characteristic determination at low cost.

Description will be made below on distinguishing configurations extracted from the above-described embodiments.

### [Configuration 1]

A current leakage detection device (20) that detects current leakage between a power supply path (L1, L2) connected to a terminal of a battery (10) and a ground (FG), the current leakage detection device comprising:
a first voltage-dividing circuit (30) connected to the power supply path at one end and connected to the ground at another end, thus being put in a current-carrying state;
a second voltage-dividing circuit (40) connected in parallel with respect to the first voltage-dividing circuit with one end connected to the power supply path and another end connected to the ground, thus being put in the current-carrying state;
a switching unit (Sz, 50) configured to be able to switch between the current-carrying state and a current-blocked state of the second voltage-dividing circuit; and
a controller (70) configured to control the switching unit and input a divided voltage value of the first voltage-dividing circuit to detect the current leakage, wherein
the controller is configured to be able to input the divided voltage value from the first voltage-dividing circuit and a divided voltage value from the second voltage-dividing circuit, the controller being configured to perform:
   a first input step of controlling the switching unit to switch the second voltage-dividing circuit to the current-carrying state, inputting the first divided voltage value from the first voltage-dividing circuit, and inputting the second divided voltage value from the second voltage-dividing circuit;
   a second input step of controlling, after the first input step, the switching unit to switch the second voltage-dividing circuit to the current-blocked state and inputting a third divided voltage value from the first voltage-dividing circuit;
   a characteristic determination step of determining whether there is an abnormality in the first voltage-dividing circuit and the second voltage-dividing circuit based on the first divided voltage value and the second divided voltage value; and
   a current leakage detection step of detecting the current leakage based on the first divided voltage value and the third divided voltage value.

### [Configuration 2]

The current leakage detection device according to Configuration 1, in which
the switching unit is configured to be able to switch between the current-carrying state and the current-blocked state of the first voltage-dividing circuit and switch between the current-carrying state and the current-blocked state of the second voltage-dividing circuit, and
the controller is configured to perform:
   an initial value acquirement step of controlling the switching unit to switch the first voltage-dividing circuit and the second voltage-dividing circuit to the current-blocked state, acquiring a first initial value based on a signal inputted from the first voltage-dividing circuit put in the current-blocked state, and acquiring a second initial value based on a signal inputted from the second voltage-dividing circuit put in the current-blocked state; and
   a correction step of correcting a deviation due to circuit characteristics of the first voltage-dividing circuit based on the first initial value acquired in the initial value acquirement step and correcting a deviation due to circuit characteristics of the second voltage-dividing circuit based on the second initial value acquired in the initial value acquirement step.

### [Configuration 3]

The current leakage detection device according to Configuration 2, in which
the controller is configured to:
in a case where any one of the first voltage-dividing circuit and the second voltage-dividing circuit is in the current-carrying state, input the divided voltage value from the first voltage-dividing circuit or the second voltage-dividing circuit in the current-carrying state through a heavy filter circuit (202) with a large time constant; and
in a case where any one of the first voltage-dividing circuit and the second voltage-dividing circuit is in the current-blocked state, input the signal from the first voltage-dividing circuit or the second voltage-dividing circuit in the current-blocked state through a light filter circuit (204) with a small time constant.

### [Configuration 4]

The current leakage detection device according to any one of Configurations 1 to 3, in which in the current leakage detection step, the controller is configured to:
compute a value of an insulation resistance with use of a detected voltage of the first voltage-dividing circuit calculated from the first divided voltage value, a detected voltage of the first voltage-dividing circuit calculated from the third divided voltage value, a value of a detection resistance of the first voltage-dividing circuit, and a value of a detection resistance of the second voltage-dividing circuit, and
detect the current leakage from the value of the insulation resistance.

### [Configuration 5]

The current leakage detection device according to Configuration 4, in which in the current leakage detection step, the controller is configured to detect the current leakage as being ongoing without computing the value of the insulation resistance in a case where the detected voltage of the first voltage-dividing circuit calculated from the first divided voltage value is less than a first threshold or in a case where the detected voltage of the first voltage-dividing circuit calculated from the third divided voltage value is less than a second threshold.

### [Configuration 6]

The current leakage detection device according to any one of Configurations 1 to 5, in which
the switching unit includes a first switch (Si) and a second switch (Sz) connected in series to the first switch,
the one end of the first voltage-dividing circuit is connected to a negative-side power supply path, and the other end of the first voltage-dividing circuit is connected to between the first switch and the second switch and connected in series to the ground via the first switch, and
the one end of the second voltage-dividing circuit is connected to the negative-side power supply path, and the other end of the second voltage-dividing circuit is connected in series to, out of both ends of the second switch, one end which is not connected to the first switch and connected in series to the ground via the second switch and the first switch.

### [Configuration 7]

The current leakage detection device according to any one of Configurations 1 to 5, in which
the switching unit includes a first switch (Si) and a second switch (Sz) connected in series to the first switch,
the one end of the first voltage-dividing circuit is connected to the ground, and the other end of the first voltage-dividing circuit is connected to between the first switch and the second switch and connected in series to a positive-side power supply path via the first switch, and
the one end of the second voltage-dividing circuit is connected to the ground, and the other end of the second voltage-dividing circuit is connected in series to, out of both ends of the second switch, one end which is not connected to the first switch and connected in series to the positive-side power supply path via the second switch and the first switch.

### [Configuration 8]

The current leakage detection device according to any one of Configurations 1 to 5, in which
the switching unit includes a first switch (Si) and a second switch (Sz),
the first voltage-dividing circuit includes a first A detection resistance (30a) and a first B detection resistance (30b) connected in series to the first A detection resistance, the first A detection resistance being connected to the ground, the first B detection resistance being connected to a negative-side power supply path (L2, SG) connected to a negative terminal of the battery,
the second voltage-dividing circuit includes a second A detection resistance (40a) and a second B detection resistance (40b) connected in series to the second A detection resistance, the second A detection resistance being connected to the ground, the second B detection resistance being connected to the negative-side power supply path,
the controller is:
   connected to the negative-side power supply path and configured to measure a signal inputted with an assumption that the negative-side power supply path is a reference of potential;
   configured to input the signal from the first voltage-dividing circuit through a first output line (L11), the first output line being connected, at one end, to a first connection point (P1) between the first A detection resistance and the first B detection resistance and connected, at another end, to the controller; and
   configured to input the signal from the second voltage-dividing circuit through a second output line (L12), the second output line being connected, at one end, to a second connection point (P2) between the second A detection resistance and the second B detection resistance and connected, at another end, to the controller,
the first switch is connected to between the first connection point and the ground and configured to be able to switch between the current-carrying state and the current-blocked state between the first connection point and the first A detection resistance, and
the second switch is connected to between the second connection point and the ground and configured to be able to switch between the current-carrying state and the current-blocked state between the second connection point and the second A detection resistance.

### [Configuration 9]

The current leakage detection device according to any one of Configurations 1 to 5, in which
the switching unit includes a first switch (Si) and a second switch (Sz),
the first voltage-dividing circuit includes a first A detection resistance (30a) and a first B detection resistance (30b) connected in series to the first A detection resistance, the first A detection resistance being connected to a positive-side power supply path (L1) connected to a positive terminal of the battery, the first B detection resistance being connected to the ground,
the second voltage-dividing circuit includes a second A detection resistance (40a) and a second B detection resistance (40b) connected in series to the second A detection resistance, the second A detection resistance being connected to the positive-side power supply path, the second B detection resistance being connected to the ground,
the controller is:
   connected to the ground and configured to measure a signal inputted with an assumption that the ground is a reference of potential;
   configured to input the signal from the first voltage-dividing circuit through a first output line (L11), the first output line being connected, at one end, to a first connection point (P1) between the first A detection resistance and the first B detection resistance and connected, at another end, to the controller; and
   configured to input the signal from the second voltage-dividing circuit through a second output line (L12), the second output line being connected, at one end, to a second connection point (P2) between the second A detection resistance and the second B detection resistance and connected, at another end, to the controller,
the first switch is connected to between the first connection point and the positive-side power supply path and configured to be able to switch between the current-carrying state and the current-blocked state between the first connection point and the first A detection resistance, and
the second switch is connected to between the second connection point and the positive-side power supply path and configured to be able to switch between the current-carrying state and the current-blocked state between the second connection point and the second A detection resistance.

Although the present disclosure has been described in reference to the embodiments, it should be understood that the present disclosure is not limited to the embodiments and structures. The present disclosure also encompasses various modification examples and modifications within the equivalent range. In addition, various combinations and forms, as well as other combinations and forms including only one element, more or less, are within the scope and spirit of the present disclosure.

What is claimed is:

1. A current leakage detection device that detects current leakage between a power supply path connected to a terminal of a battery and a ground, the current leakage detection device comprising:
a first voltage-dividing circuit connected to the power supply path at one end and connected to the ground at another end, thus being put in a current-carrying state;
a second voltage-dividing circuit connected in parallel with respect to the first voltage-dividing circuit with one end connected to the power supply path and another end connected to the ground, thus being put in the current-carrying state;
a switching unit configured to be able to switch between the current-carrying state and a current-blocked state of the second voltage-dividing circuit; and
a controller configured to control the switching unit and input a divided voltage value of the first voltage-dividing circuit to detect the current leakage, wherein
the controller is configured to be able to input the divided voltage value from the first voltage-dividing circuit and a divided voltage value from the second voltage-dividing circuit, the controller being configured to perform:
a first input step of controlling the switching unit to switch the second voltage-dividing circuit to the current-carrying state, inputting the first divided voltage value from the first voltage-dividing circuit, and inputting the second divided voltage value from the second voltage-dividing circuit;
a second input step of controlling, after the first input step, the switching unit to switch the second voltage-dividing circuit to the current-blocked state and inputting a third divided voltage value from the first voltage-dividing circuit;
a characteristic determination step of determining whether there is an abnormality in the first voltage-dividing circuit and the second voltage-dividing circuit based on the first divided voltage value and the second divided voltage value; and
a current leakage detection step of detecting the current leakage based on the first divided voltage value and the third divided voltage value.

2. The current leakage detection device according to claim 1, wherein
the switching unit is configured to be able to switch between the current-carrying state and the current-blocked state of the first voltage-dividing circuit and switch between the current-carrying state and the current-blocked state of the second voltage-dividing circuit, and
the controller is configured to perform:
an initial value acquirement step of controlling the switching unit to switch the first voltage-dividing circuit and the second voltage-dividing circuit to the current-blocked state, acquiring a first initial value based on a signal inputted from the first voltage-dividing circuit put in the current-blocked state, and acquiring a second initial value based on a signal inputted from the second voltage-dividing circuit put in the current-blocked state; and
a correction step of correcting a deviation due to circuit characteristics of the first voltage-dividing circuit based on the first initial value acquired in the initial value acquirement step and correcting a deviation due to circuit characteristics of the second voltage-dividing circuit based on the second initial value acquired in the initial value acquirement step.

3. The current leakage detection device according to claim 2, wherein
the controller is configured to:
in a case where any one of the first voltage-dividing circuit and the second voltage-dividing circuit is in the current-carrying state, input the divided voltage value from the first voltage-dividing circuit or the second voltage-dividing circuit in the current-carrying state through a heavy filter circuit with a large time constant; and
in a case where any one of the first voltage-dividing circuit and the second voltage-dividing circuit is in the current-blocked state, input the signal from the first voltage-dividing circuit or the second voltage-dividing circuit in the current-blocked state through a light filter circuit with a small time constant.

4. The current leakage detection device according to claim 1, wherein in the current leakage detection step, the controller is configured to:
compute a value of an insulation resistance with use of a detected voltage of the first voltage-dividing circuit calculated from the first divided voltage value, a detected voltage of the first voltage-dividing circuit calculated from the third divided voltage value, a value of a detection resistance of the first voltage-dividing circuit, and a value of a detection resistance of the second voltage-dividing circuit, and
detect the current leakage from the value of the insulation resistance.

5. The current leakage detection device according to claim 4, wherein in the current leakage detection step, the controller is configured to detect the current leakage as being ongoing without computing the value of the insulation resistance in a case where the detected voltage of the first voltage-dividing circuit calculated from the first divided voltage value is less than a first threshold or in a case where the detected voltage of the first voltage-dividing circuit calculated from the third divided voltage value is less than a second threshold.

6. The current leakage detection device according to claim 2, wherein
the switching unit includes a first switch and a second switch connected in series to the first switch,
the one end of the first voltage-dividing circuit is connected to a negative-side power supply path, and the other end of the first voltage-dividing circuit is connected to between the first switch and the second switch and connected in series to the ground via the first switch, and
the one end of the second voltage-dividing circuit is connected to the negative-side power supply path, and the other end of the second voltage-dividing circuit is connected in series to, out of both ends of the second switch, one end which is not connected to the first switch and connected in series to the ground via the second switch and the first switch.

7. The current leakage detection device according to claim 4, wherein
the switching unit includes a first switch and a second switch connected in series to the first switch,
the one end of the first voltage-dividing circuit is connected to a negative-side power supply path, and the other end of the first voltage-dividing circuit is connected to between the first switch and the second switch and connected in series to the ground via the first switch, and
the one end of the second voltage-dividing circuit is connected to the negative-side power supply path, and the other end of the second voltage-dividing circuit is connected in series to, out of both ends of the second switch, one end which is not connected to the first switch and connected in series to the ground via the second switch and the first switch.

8. The current leakage detection device according to claim 2, wherein
the switching unit includes a first switch and a second switch connected in series to the first switch,
the one end of the first voltage-dividing circuit is connected to the ground, and the other end of the first voltage-dividing circuit is connected to between the first switch and the second switch and connected in series to a positive-side power supply path via the first switch, and
the one end of the second voltage-dividing circuit is connected to the ground, and the other end of the second voltage-dividing circuit is connected in series to, out of both ends of the second switch, one end which is not connected to the first switch and connected in series to the positive-side power supply path via the second switch and the first switch.

9. The current leakage detection device according to claim 4, wherein
the switching unit includes a first switch and a second switch connected in series to the first switch,
the one end of the first voltage-dividing circuit is connected to the ground, and the other end of the first voltage-dividing circuit is connected to between the first switch and the second switch and connected in series to a positive-side power supply path via the first switch, and
the one end of the second voltage-dividing circuit is connected to the ground, and the other end of the second voltage-dividing circuit is connected in series to, out of both ends of the second switch, one end which is not connected to the first switch and connected in series to the positive-side power supply path via the second switch and the first switch.

10. The current leakage detection device according to claim 2, wherein
the switching unit includes a first switch and a second switch,
the first voltage-dividing circuit includes a first A detection resistance and a first B detection resistance connected in series to the first A detection resistance, the first A detection resistance being connected to the ground, the first B detection resistance being connected to a negative-side power supply path connected to a negative terminal of the battery,
the second voltage-dividing circuit includes a second A detection resistance and a second B detection resistance connected in series to the second A detection resistance, the second A detection resistance being connected to the ground, the second B detection resistance being connected to the negative-side power supply path,
the controller is:
connected to the negative-side power supply path and configured to measure a signal inputted with an assumption that the negative-side power supply path is a reference of potential;
configured to input the signal from the first voltage-dividing circuit through a first output line, the first output line being connected, at one end, to a first connection point between the first A detection resistance and the first B detection resistance and connected, at another end, to the controller; and
configured to input the signal from the second voltage-dividing circuit through a second output line, the second output line being connected, at one end, to a second connection point between the second A detection resistance and the second B detection resistance and connected, at another end, to the controller,
the first switch is connected to between the first connection point and the ground and configured to be able to switch between the current-carrying state and the current-blocked state between the first connection point and the first A detection resistance, and
the second switch is connected to between the second connection point and the ground and configured to be able to switch between the current-carrying state and the current-blocked state between the second connection point and the second A detection resistance.

11. The current leakage detection device according to claim 4, wherein
the switching unit includes a first switch and a second switch,
the first voltage-dividing circuit includes a first A detection resistance and a first B detection resistance connected in series to the first A detection resistance, the first A detection resistance being connected to the ground, the first B detection resistance being connected to a negative-side power supply path connected to a negative terminal of the battery,
the second voltage-dividing circuit includes a second A detection resistance and a second B detection resistance connected in series to the second A detection resistance, the second A detection resistance being connected to the ground, the second B detection resistance being connected to the negative-side power supply path,
the controller is:
connected to the negative-side power supply path and configured to measure a signal inputted with an assumption that the negative-side power supply path is a reference of potential;
configured to input the signal from the first voltage-dividing circuit through a first output line, the first output line being connected, at one end, to a first connection point between the first A detection resistance and the first B detection resistance and connected, at another end, to the controller; and
configured to input the signal from the second voltage-dividing circuit through a second output line, the second output line being connected, at one end, to a second connection point between the second A detection resistance and the second B detection resistance and connected, at another end, to the controller,
the first switch is connected to between the first connection point and the ground and configured to be able to switch between the current-carrying state and the current-blocked state between the first connection point and the first A detection resistance, and
the second switch is connected to between the second connection point and the ground and configured to be able to switch between the current-carrying state and the current-blocked state between the second connection point and the second A detection resistance.

12. The current leakage detection device according to claim 2, wherein
the switching unit includes a first switch and a second switch,
the first voltage-dividing circuit includes a first A detection resistance and a first B detection resistance connected in series to the first A detection resistance, the first A detection resistance being connected to a positive-side power supply path connected to a positive terminal of the battery, the first B detection resistance being connected to the ground,
the second voltage-dividing circuit includes a second A detection resistance and a second B detection resistance connected in series to the second A detection resistance, the second A detection resistance being connected to the positive-side power supply path, the second B detection resistance being connected to the ground,
the controller is:
connected to the ground and configured to measure a signal inputted with an assumption that the ground is a reference of potential;
configured to input the signal from the first voltage-dividing circuit through a first output line, the first output line being connected, at one end, to a first connection point between the first A detection resistance and the first B detection resistance and connected, at another end, to the controller; and
configured to input the signal from the second voltage-dividing circuit through a second output line, the second output line being connected, at one end, to a second connection point between the second A detection resistance and the second B detection resistance and connected, at another end, to the controller,
the first switch is connected to between the first connection point and the positive-side power supply path and configured to be able to switch between the current-carrying state and the current-blocked state between the first connection point and the first A detection resistance, and
the second switch is connected to between the second connection point and the positive-side power supply path and configured to be able to switch between the current-carrying state and the current-blocked state between the second connection point and the second A detection resistance.

13. The current leakage detection device according to claim 4, wherein
the switching unit includes a first switch and a second switch,
the first voltage-dividing circuit includes a first A detection resistance and a first B detection resistance connected in series to the first A detection resistance, the first A detection resistance being connected to a positive-side power supply path connected to a positive terminal of the battery, the first B detection resistance being connected to the ground,
the second voltage-dividing circuit includes a second A detection resistance and a second B detection resistance connected in series to the second A detection resistance, the second A detection resistance being connected to the positive-side power supply path, the second B detection resistance being connected to the ground,
the controller is:
connected to the ground and configured to measure a signal inputted with an assumption that the ground is a reference of potential;
configured to input the signal from the first voltage-dividing circuit through a first output line, the first output line being connected, at one end, to a first connection point between the first A detection resistance and the first B detection resistance and connected, at another end, to the controller; and
configured to input the signal from the second voltage-dividing circuit through a second output line, the second output line being connected, at one end, to a second connection point between the second A detection resistance and the second B detection resistance and connected, at another end, to the controller,
the first switch is connected to between the first connection point and the positive-side power supply path and configured to be able to switch between the current-carrying state and the current-blocked state between the first connection point and the first A detection resistance, and
the second switch is connected to between the second connection point and the positive-side power supply path and configured to be able to switch between the current-carrying state and the current-blocked state between the second connection point and the second A detection resistance.
